(19) United States
(12) Patent Application Publication
(10) Pub. No.: US 2026/0051852 A1
(43) Pub. Date: Feb. 19, 2026

(54) SAMPLE AND HOLD CIRCUIT WITH LOW DROOP RATE FOR BATTERY POWERED SYSTEMS

(71) Applicant: Infineon Technologies AG, Neubiberg (DE)

(72) Inventors: Lorenzo Pulcini, Savona (IT); Paolo Del Croce, Villach (AT); Andrea Baschirotto, Tortona (IT)

(21) Appl. No.: 18/797,205

(22) Filed: Aug. 7, 2024

(51) Int. Cl. H03F 1/02; H03F 3/45

(52) U.S. Cl. CPC H03F 1/0205; H03F 3/45475; H03F 2203/45116

(57) ABSTRACT

A sample and hold circuit may comprise an operational amplifier including a first op-amp input, a second op-amp input, and an op-amp output. The sample and hold circuit may also include a first switch connected between the first op-amp input and a supply node, a second switch connected between the second op-amp input and the supply node, a first capacitor connected between the first op-amp input and a ground node, a second capacitor connected to the second op-amp input, a third switch connected between the second capacitor and a sample input, and a fourth switch connected between the second capacitor and the op-amp output.

### TECHNICAL FIELD

The disclosure relates to sample and hold circuits in battery operated systems where it is desirable to minimize power consumption.

### BACKGROUND

It is desirable to minimize power consumption in high-efficiency or battery-operated systems, such as vehicle systems when the vehicle is turned off. In such systems, there are several circuit elements or blocks, like reference voltage generators, that may remain active and consume a significant amount of power to produce a constant or steady voltage, e.g., even when the system is turned off.

### SUMMARY

This disclosure describes a number of examples of a sample and hold circuit. The described sample and hold circuits may be useful for battery-operated systems, such as vehicle systems. In such systems, it may be desirable to maintain a constant or steady voltage, e.g., even when the system is turned off.

In some examples, this disclosure describes a circuit that comprises an operational amplifier including a first op-amp input, a second op-amp input, and an op-amp output; a first switch connected between the first op-amp input and a supply node; a second switch connected between the second op-amp input and the supply node; a first capacitor connected between the first op-amp input and a ground node; a second capacitor connected to the second op-amp input; a third switch connected between the second capacitor and a sample input; and a fourth switch connected between the second capacitor and the op-amp output. The circuit may be configured to perform a sample and hold operation on the sample input.

In some examples, this disclosure describes a method of operating a circuit to perform a sample and hold operation on a sample input, wherein the circuit comprises: an operational amplifier including a first op-amp input, a second op-amp input, and an op-amp output; a first switch connected to the first op-amp input and a supply node; a second switch connected to the second op-amp input and the supply node; a first capacitor connected between the first op-amp input and a ground node; a second capacitor connected to the second op-amp input; a third switch connected between the second capacitor and the sample input; and a fourth switch connected between the second capacitor and the op-amp output. The method may comprise performing a sample phase; and performing a hold phase. In some examples, the sample phase comprises controlling the first switch closed, controlling the second switch closed, controlling the third switch closed, and controlling the fourth switch open, and in some examples, the hold phase comprises controlling the first switch open, controlling the second switch is open, controlling the third switch open, and controlling the fourth switch closed.

The details of one or more examples of the disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 is an example circuit diagram of a sample and hold circuit consistent with this disclosure.

FIG. 2 illustrates a clock signal that may define a sample phase and a hold phase consistent with this disclosure.

FIG. 3 is another example circuit diagram of a sample and hold circuit consistent with this disclosure.

FIG. 4 is a block diagram consistent with an example of this disclosure.

FIG. 5 is another block diagram consistent with an example of this disclosure.

FIG. 6 is a more detailed block diagram consistent with an example of this disclosure.

FIG. 7 is a circuit diagram showing a multiplier circuit that may be combined with a sample and hold circuit.

FIG. 8 is a circuit diagram showing a portion of a sample and hold circuit that may be combined with the multiplier circuit shown in FIG. 7.

FIG. 9 is a circuit diagram showing a combined multiplier circuit sample and hold circuit that both use the same operational amplifier at different phases.

FIG. 10-12 are example flow diagrams consistent with this disclosure.

### DETAILED DESCRIPTION

This disclosure describes examples of sample and hold circuits that may help reduce power consumption in battery operated systems. Power consumption is a desirable parameter to improve for high-efficiency or battery-operated systems, such as vehicle systems e.g., the vehicle is turned off. In these cases, there are several blocks, like reference voltage generators, that may remain active and consume a significant amount of power to produce a DC (direct current) voltage. The amount of power used to maintain voltage generators can be significant, and in some cases, the circuits may be designed under other constrains, such as small area, or other factors that may reduce the power efficiency of the circuits. Solutions to reduce such power consumption, e.g., for voltage generators or other circuits operating in vehicular systems, is desirable.

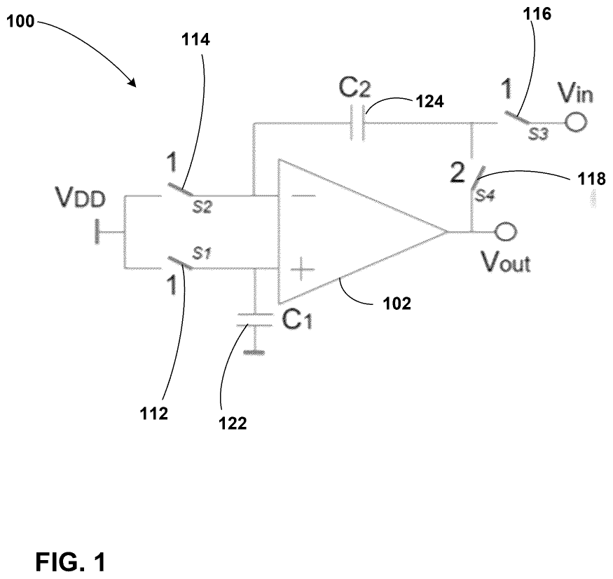

One solution for reducing power consumption for voltage reference generators is sampling the reference voltages and holding this voltage with a long sample and hold circuit, e.g., controlled by a very long clock signal and turning off the reference voltage generator. FIG. 1 is one example of a circuit 100 that may be configured to perform a sample and hold operation consistent with this disclosure. Circuit 100 comprises an operational amplifier 102 including a first op-amp input (e.g., the + input), a second op-amp input (e.g., the − input), and an op-amp output (e.g., corresponding to Vout). A first switch (S1) 112 is connected between the first op-amp input and a supply node, and a second switch (S2) 114 is connected between the second op-amp input and the supply node. A first capacitor (C1) 122 is connected between the first op-amp input and a ground node, and a second capacitor (C2) 124 is connected to the second op-amp input. A third switch (S3) 116 is connected between the second capacitor 124 and a sample input (e.g., corresponding to Vin), and a fourth switch (S4) 118 is connected between the second capacitor 124 and the op-amp output (e.g., corresponding to Vout).

According to some examples of this disclosure, circuit 100 may be configured to perform a sample and hold operation on the sample input, and for example, the sample and hold operation may hold the sample input voltage on the op-amp output for greater than 100 milliseconds. The sample and hold operation includes a sample phase and a hold phase, wherein in some examples a length of the hold phase greater than 500 times a length of the sample phase. Consistent with FIG. 1, in some examples, during the sample phase, first switch 112 is closed, second switch 114 is closed, third switch is closed 116, and fourth switch 118 is open. Then, during the hold phase, first switch 112 is open, second switch 114 is open, third switch 116 is open, and fourth switch 118 is closed.

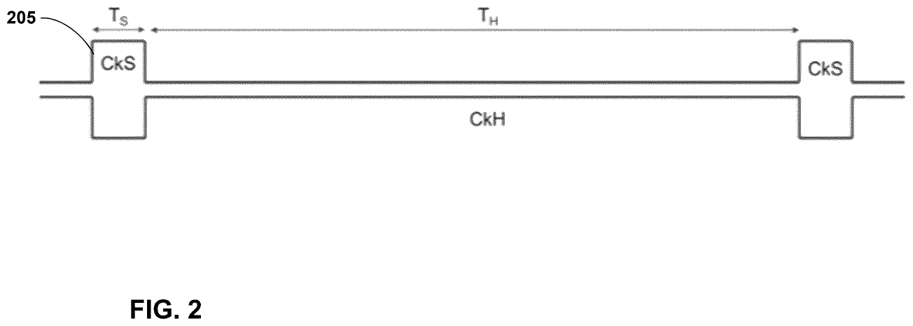

In some examples, the sample phase and the hold phase are defined by a clock signal, and first switch 112, second switch 114, third switch 116, and fourth switch 118 are configured to receive gate control signals that are defined based on the clock signal. FIG. 2 shows one example of a clock signal 205. T_{S} may refer to a sample phase, and T_{H} may refer to the hold phase, and the edges of CkS signal may be used to define the timing of gate control signals for controlling switches 112, 114, 116, 118 as set forth above. In some examples, T_{H} may be greater than 100 milliseconds. In some examples, a length of T_{H} may be greater 500 times a length of T_{S}.

Clock signal 205 may be generated in any of a variety of way, such as by using digital frequency dividers (e.g., cascaded D-Flip Flops). In some cases, rather than relying solely on digital frequency dividers (e.g., cascaded D-Flip Flops), techniques for generating clock signal 205 may use an analog frequency divider, or possibly a combination of an analog frequency divider and digital frequency dividers. In any case, clock signal 205 with a short sample period and a long hold period may be effective for defining the timing for controlling the gates of switches 112, 114, 116, 118.

In the case where a voltage reference generator is always ON (and no sample and hold operating is used) the average power consumption is P_{VRG}, while with a sample and hold scheme consistent with the timing shown in FIG. 2, and where a sample and hold circuit is always ON while reference generator is ON only during the sampling phase, the average power consumption would be:

$${P}_{S \& H} = ( ( {P}_{VRG} + {P}_{S \& H} ) \cdot {T}_{S} + {P}_{S \& H} \cdot {T}_{H} ) / ( {T}_{S} + {T}_{H} )$$

This allows significant power saving, in particular, if the duty cycle (i.e., the ratio between the time when the voltage reference generator is on and the full period including on and off time, DC=T_{S}/(T_{S}+T_{H})) is small. This is because the power consumption of the sample and hold circuit is expected to be lower than the power consumption of the Reference Voltage Generator.

As an example, assuming P_{VRG}=1 uW, P_{S&H}=200 nW, T_{S}=5 usec, T_{H}=100 msec, the average power without sample and hold, would be

$${P}_{noS \& H} = {P}_{VRG} = 1 uW$$

while the solution with sample and hold would consume an average power given by:

$${P}_{S \& H} = ( ( {P}_{VRG} + {P}_{S \& H} ) \cdot {T}_{S} + {P}_{S \& H} \cdot {T}_{H} ) / ( {T}_{S} + {T}_{H} ) = 200 nW$$

Thus, with this example, a sample and hold circuit can yield 80% power saving results. This can be achieved by exploiting the sample and hold circuit consuming a power much lower than the Voltage Generator, and also ensuring a low-droop-rate which enable long hold time (T_{H}).

One desirable aspect of this circuits described herein is the ability to achieve low-droop rate and long hold time. Conventional circuits for sample and holding a voltage may have a problem of leakage current causing voltage droop on the output capacitor. In some examples, the circuits and techniques of this disclosure may have reduced droop relative to conventional sample and hold circuits and may have very little (or acceptable) droop over the amount of time associated with hold phases.

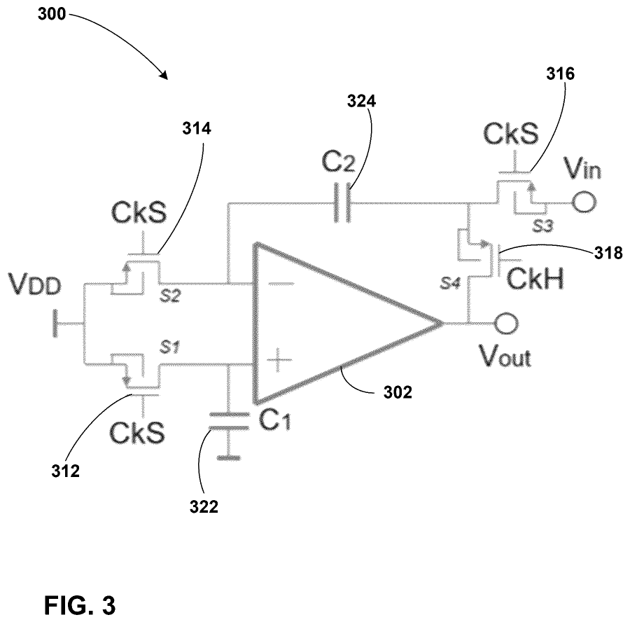

FIG. 3 is another example of a circuit, i.e., circuit 300, that may be configured to perform a sample and hold operation consistent with this disclosure. Circuit 300 comprises an operational amplifier 302 including a first op-amp input (e.g., the + input), a second op-amp input (e.g., the − input), and an op-amp output (e.g., corresponding to Vout). A first switch (S1) 312 is connected between the first op-amp input and a supply node, and a second switch (S2) 314 is connected between the second op-amp input and the supply node. A first capacitor (C1) 322 is connected between the first op-amp input and a ground node, and a second capacitor (C2) 324 is connected to the second op-amp input. A third switch (S3) 316 is connected between the second capacitor 324 and a sample input (e.g., corresponding to Vin), and a fourth switch (S4) 118 is connected between the second capacitor 324 and the op-amp output (e.g., corresponding to Vout). First capacitor 322 and second capacitor 324 may be matched with approximately a same capacitance. In some examples, the capacitive rating and structure of first capacitor 322 and second capacitor 324 may be similar or identical.

According to some examples of this disclosure, circuit 300 may be configured to perform a sample and hold operation on the sample input, and for examples, the sample and hold operation may hold the sample input voltage on the op-amp output for greater than 100 milliseconds. In some examples, the sample and hold operation includes a sample phase and a hold phase, wherein a length of the hold phase greater than 500 times a length of the sample phase. Consistent with FIG. 3, in some examples, during the sample phase, first switch 312 is closed, second switch 314 is closed, third switch 316 is closed, and fourth switch 318 is open. Then, during the hold phase, first switch 312 is open, second switch 314 is open, third switch 316 is open, and fourth switch 318 is closed.

In some examples, the sample phase and the hold phase are defined by a clock signal like signal 205 of FIG. 2, and first switch 312, second switch 314, third switch 316, and fourth switch 318 may be configured to receive gate control signals that are defined based on the clock signal.

In the example shown in FIG. 3, first switch 312 and second switch 314 are both PMOS transistors that each include a source connection to the supply node and a bulk connection to the supply node (as shown by the illustrated circuit structure with the bulk connected to the source at supply V_{DD}). This is desirable to limit leakage current and avoid droop during the hold phase. After capacitor 324 is charged to V_{DD} during the sample phase, if the bulk of second switch 314 is connected to that V_{DD} (i.e., the supply), little or no leakage current would flow during the hold phase, e.g., through a body diode of second power switch 314, because the supply V_{DD} connected to the bulk of second switch 314 is similar to the charge placed on second capacitor 324 during the sample phase.

In some examples, the circuit 300 shown in FIG. 3 may operate as follows:
During a sampling phase (phase CkS as shown in FIG. 2), the input signal is sampled on C₂ referred to V_{DD}, while C₁ is precharged to V_{DD}.
During a hold phase (phase CkH as shown in FIG. 2), sampling cap C₂ is connected in feedback, while capacitor C₁ is connected to the opamp positive input node forcing it at V_{DD}.
Without the leakage current, as the opamp input positive node is at V_{DD}, capacitor C₂ when it is connected in feedback, forces

$${V}_{out} = {V}_{in}$$

In presence of the leakage current, there may be at least two features or design factors that can help to avoid droop in sample and hold circuits. As the opamp input nodes are biased at V_{DD} and the n-doped bulk are connected at V_{DD} as well. As such, this results in VBS=0 and, then, no bulk leakage current flows. Concerning the channel current, as MOS switches can be connected between opamp input node (that are at V_{DD}) and V_{DD}, there is V_{DS}=0, and then no Channel Current would flow, as well. However, in case the opamp input node would move (e.g., for offset, finite gain, or other reasons) this could result in V_{DS}≠0 and then a channel current would flow in both S1 and S2. In this case, I_{S1} can be collected in the cap C₁ and this can force the opamp positive input node to move as:

$${V}_{P} = {V}_{Po} + t * {I}_{S 1} / {C}_{1}$$

where V_{Po}=V_{DD}. Notice that I_{S1} depends on V_{DS1}.

In a similar way, any leakage channel current from switch S2 may be collected on the C₂ armature producing a change in the voltage on C₂ as

$${V}_{C 2} = {V}_{C 2 o} + t * {I}_{S 2} / {C}_{2}$$

If S1=S2 and opamp input nodes Vₚ=Vₘ (even if they are different from V_{DD}), the leakage currents I_{S1} and I_{S2} can be assumed to be identical (or very similar) as V_{DS1}=V_{DS2}. Furthermore, if C₂ is designed to be equal to C₁, the movement of Vₚ (due to I_{S1} loading C₁) is compensated by the movement on Vₘ (due to I_{S2} loading C₂), and, therefore, Vₒᵤₜ does not change (nonetheless Vₚ and Vₘ move).

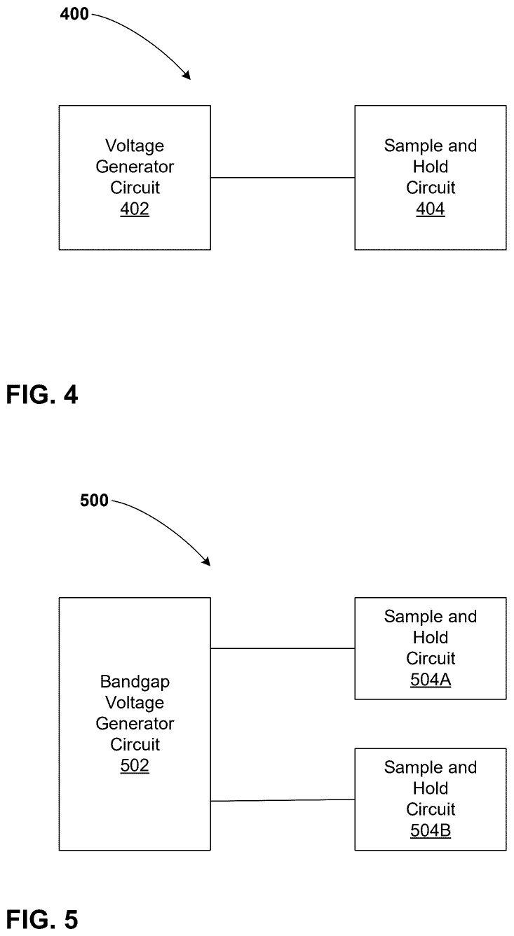

FIG. 4 is a basic block diagram consistent with an example of this disclosure. As shown, a circuit 400 may include a voltage generator circuit 402 and a sample and hold circuit 404. Voltage generator circuit 402 may be disabled after generating a voltage, and sample and hold circuit 404 may sample the voltage and hold the voltage steady while voltage generator circuit 402 is disabled, which can save power in vehicular systems or other battery-operated systems. In some cases, voltage generator circuit 402 is configured to generate a voltage during a sample phase, and voltage generator circuit 402 is disabled during a hold phase. Sample and hold circuit 404 samples the voltage from voltage generator circuit 402 during the sample phase and holds the voltage during the hold phase. In some examples, voltage generator circuit 402 is configured to generate a voltage reference that is temperature-dependent, which may be necessary in vehicular systems or other systems where temperatures associated with circuit operation can change.

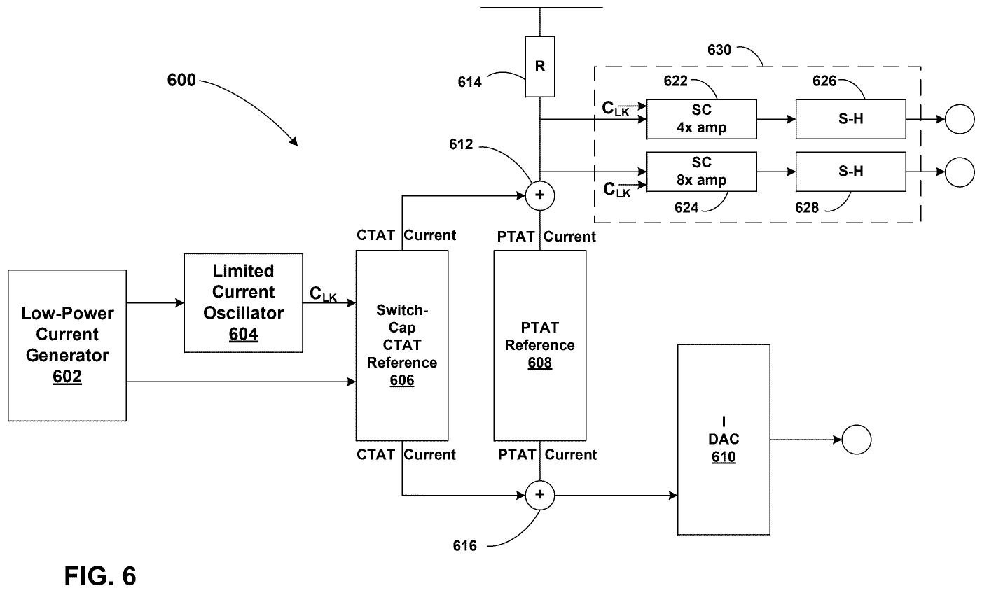

FIG. 5 is another block diagram consistent with an example of this disclosure. A circuit 500 may include a bandgap generator circuit 502, which is essentially two different voltage generator circuits configured to generate a first voltage and a second voltage. Accordingly, circuit 500 includes two different sample and hold circuits 504, 506. Bandgap generator circuit 502 may be disabled after generating the bandgap voltages, and sample and hold circuits 504, 506 may sample the voltages and hold the voltages steady while bandgap generator circuit 502 is disabled, which can save power in vehicular systems or other battery-operated systems. In some cases, bandgap generator circuit 502 is configured to generate bandgap voltages during a sample phase, and bandgap generator circuit 502 is disabled during a hold phase. Sample and hold circuits 504, 506 may be configured to sample the respective bandgap voltages from bandgap generator 502 during the sample phase, and sample and hold circuits 504, 506 may be configured to hold the bandgap voltages during the hold phase. In some examples, bandgap generator circuit 502 is configured to generate bandgap voltage references that are both temperature-dependent, which may be necessary in vehicular systems or other systems where temperatures associated with circuit operation can change. Consistent with FIG. 5, in some examples, a circuit 500 may include a first sample and hold circuit 504 for a first reference voltage of a bandgap, and circuit 500 may include a sample and hold circuit 506 for second reference voltage of the bandgap, wherein the second sample and hold circuit 506 is the same or similar to the first second sample and hold circuit 504. In some cases, second sample and hold circuit 506 is identical to first second sample and hold circuit 504.

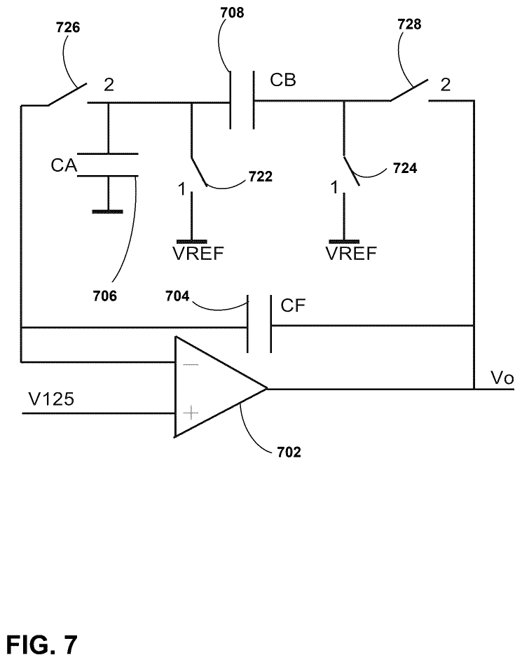

FIG. 6 is a more detailed block diagram consistent with an example of this disclosure. Circuit 600 may comprise a low-power current generator 602 and a limited current oscillator 604 that provides a clock signal (Clk). A switched-capacitor CTAT reference generator circuit 606 is configured to generate CTAT current (i.e., current that is “complementary to absolute temperature”). In addition, a PTAT reference generator circuit 608 is configured to generate PTAT current (i.e., current that is ““proportional to absolute temperature”. CTAT reference generator circuit 606 and PTAT reference generator circuit 608 may be viewed as one example of bandgap generator circuit 502.

Current digital to analog converter (I DAC) 610 may be configured to output current based a summation 616 of PTAT current and CTAT current. In addition, the CTAT current and PTAT current may be combined by at summation 612 and dropped over resistor 614. This defines voltages that can be used by multiplier circuits 622, 624 and sampled and held by sample and hold circuits. In the illustrated example, the input to multiplier circuits 622, 624 may be approximately 0.125 volt, and after multiplication, the output of amplifier circuit 622 may be 0.5 volt and the output of amplifier circuit 624 may be 1.0 volt. Any other voltages or scaling may be used to define other voltage levels consistent with this disclosure, and the example values of 0.125 volt and 0.5 volt are merely one example.

Sample and hold circuits 626, 628 may each correspond to circuit 100 of FIG. 1 or circuit 300 of FIG. 3. During sample operation, all of the units shown in FIG. 6 may be active. During the hold operation, units 614, 608, 606, 622, and 624 may all be disabled to save power. Sample and hold circuits 626, 628 using the circuit design of circuit 100 of FIG. 1 or circuit 300 of FIG. 3 can ensure that a steady voltage (without droop) is achieved for a relatively long period of time to allow for power savings in disabling units 614, 608, 606, 622, and 624 during the hold operation.

In still other examples, circuit overlap and reuse of an operational amplifier can be achieved in circuit 630, e.g., using the same operational amplifier (or a portion of the same circuit) by multiplier units 622, 624 and by sample and hold circuits 626, 628 since these elements may operate in a complementary manner.

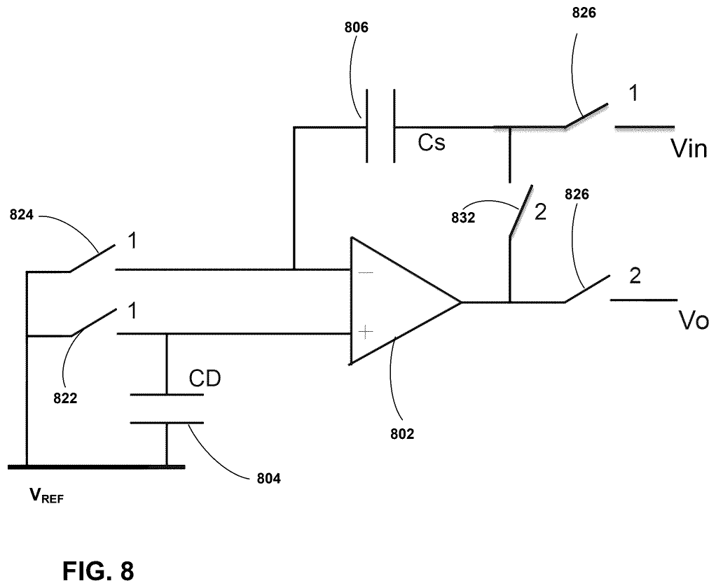

FIG. 7 is an example circuit that may correspond generally to a multiplier circuit. An operational amplifier 702 has a first op amp input (corresponding to the + input), a second op amp input (corresponding to the − input), and an op amp output (corresponding to Vo). A first capacitor (CF) 701 is arranged between the second op amp input and the op amp output. A first switch 726 is connected to the second op amp input in parallel with first capacitor 704. A second capacitor 706 is arranged in series with first switch 726 and connected to a floating ground. A second switch 722 is also arranged in series with first switch 726 and connected to a reference voltage (VREF). Third capacitor 708 is arranged in series with first switch 726. Second capacitor 706, second switch 722, and third capacitor 708 all arranged in parallel with each other. Third capacitor 708 is connected in series with third switch 724, which is connected to a reference voltage (VREF). Third capacitor 708 is also connected in series with fourth switch 728, which is connected to the op amp output (Vo). Third switch 724 and fourth switch 728 are connected in parallel.

In a first cycle (cycle 1), switches 722 and 724 are closed and switches 726 and 728 are open. In a second cycle (cycle 2) switches 726 and 728 are closed and switches 722 and 724 are open. Operational amplifier 702 may be active in cycle 1 and may be used by a sample and hold circuit during cycle 2 of the circuit shown in FIG. 7.

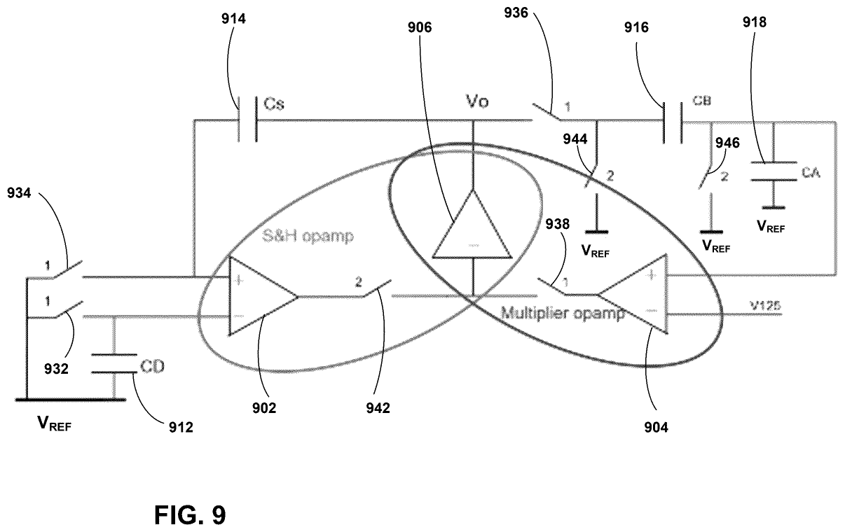

FIG. 8 is another example of a portion of a sample and hold circuit 800. In this case, circuit 800 comprises an operational amplifier 802 including a first op-amp input (corresponding to the + input), a second op-amp input (corresponding to the − input), and an op-amp output (corresponding to Vo). Circuit 800 includes a first switch 822 connected between the first op-amp input and a supply node (in this case corresponding to V_{REF} which in some examples may correspond to an N-doped substrate). Circuit 800 also includes a second switch connected between the second op-amp input and the V_{REF} node, a first capacitor 804 connected between the first op-amp input and the V_{REF} node, and a second capacitor connected to the second op-amp input. A third switch 826 and a fourth switch 883 is connected in series with the second capacitor 806, and fourth switch 832 is arranged in parallel with operational amplifier 802 such that capacitor 806 is also arranged in parallel with second capacitor 806. A fifth switch 826 is connected to capacitor 806 in parallel with fourth switch 832.

By combining the circuits of FIG. 7 and FIG. 8, a sample and hold circuit similar to that of FIGS. 1 and 3 can be achieved, while also achieving efficiencies by reusing part of the same circuit during complementary cycles of a multiplier circuit and a sample and hold circuit.

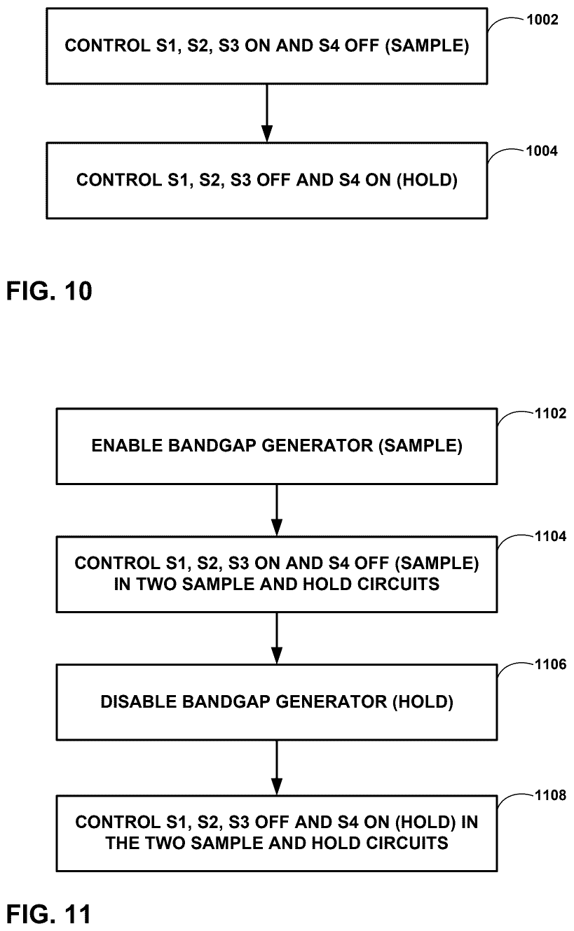

FIG. 9 shows one example circuit that may be a combination of the circuits of FIGS. 7 and 8, achieving both a sample and hold circuit similar to that of FIGS. 1 and 3, while also achieving efficiencies by reusing part of the same circuit during complementary cycles of a multiplier circuit and a sample and hold circuit.

In the circuit of FIG. 9, capacitor 912 may correspond to capacitor 804 of FIG. 8, and capacitor 914 may correspond to capacitor 806. Operational amplifier 902 of FIG. 9 may correspond to operational amplifier 802 of FIG. 8, and switches 932, 934, and 942 of FIG. 9 correspond respectively to switches 822, 824 and 826 of FIG. 8.

In the circuit of FIG. 9, multiplier functionality like that achieved by the circuit of FIG. 7 may be achieved during complementary cycles with sample and hold operations such that an operational amplifier (e.g., op amp 906) may be used for both multiplication operations and for sample and hold operations. Circuit 900 also includes switches 936, 944, 946 and 938, which may operate similarly to switches in FIG. 7. In addition, circuit 900 includes capacitors 916, 918, which may be similar to capacitors 708, 706 of FIG. 7.

The control scheme for the switches shown in FIG. 9 may operate in two cycles, whereby in cycle 1, switches 932, 934,936, 938 are closed and switches 942, 944, 946 are open. Then in cycle 2, switches 942, 944, 946 are closed and switches 932, 934,936, 938 are open.

According to this disclosure, switches 942 and 938 operate in a complementary fashion such that operational amplifier 902 and operational amplifier 904 are active in complimentary cycles. An operational amplifier 906 (i.e., an Op amp second stage or output stage) may be shared by operational amplifier 902 and operational amplifier 904.

Thus, operational amplifier 906 may connected to a first circuit configured to perform a sample and hold operation, and then the same operational amplifier 906 maybe further connected to another circuit (e.g., a multiplier circuit). A circuit may be configured to use operational amplifier 906 during a sample phase of the sample and hold operation, and the another circuit (e.g., a multiplier circuit) may be configured to use the operational amplifier 906 during a hold phase of the sample and hold operation.

With the circuit shown in FIG. 9, a sample and hold circuit similar to that of FIGS. 1 and 3 can be achieved, and another circuit comprising a multiplier circuit similar to that shown in FIG. 7 may operates in a complementary clock phase relative the sample and hold circuit.

In some examples, an operational amplifier comprises a two-stage operational amplifier (i.e., op amp 902 in combination with op amp 906, or alternatively op amp 904 in combination with op amp 906). A sample and hold circuit and a multiplier circuit may each comprise a first stage (i.e., op amp 902 of the sample and hold and op amp 904 for the multiplier) of the two-stage operational amplifier. However, in some examples, the sample and hold circuit is configured to use a second stage (i.e., op amp 906) of the two stage operational amplifier during the sample phase of the sample and hold operation and the multiplier circuit is configured to use the second stage (i.e., op amp 906) of the operational amplifier during the hold phase of the sample and hold operation.

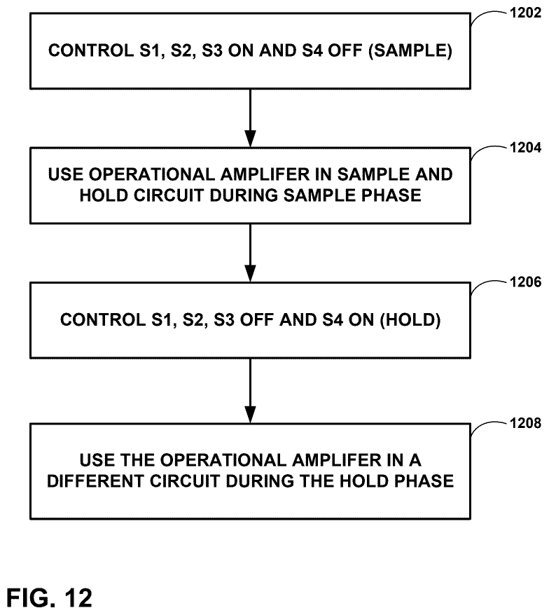

FIG. 10 is a flow diagram showing a method of this disclosure. FIG. 10 will be described from the perspective of circuit 100 or 300 of FIG. 1 or 3. As shown, a method may include a sample phase (1002) and a hold phase (1004). In the sample phase, switches S1, S2, S3 are ON and switch S4 is OFF (1002). In the hold phase, switches S1, S2, S3 are OFF and switch S4 is ON. In these examples, the switches conduct when ON and do not conduct, i.e., are non-conducting, when OFF. S1 corresponds to switch 112 of FIG. 1 or switch 312 of FIG. 3, and S2 corresponds to switch 114 of FIG. 1 or switch 314 of FIG. 3. S3 corresponds to switch 116 of FIG. 1 or switch 316 of FIG. 3, and S3 corresponds to switch 118 of FIG. 1 or switch 318 of FIG. 3.

FIG. 11 is a flow diagram showing a method of this disclosure. FIG. 11 will be described from the perspective of circuit 500 of FIG. 5. In some examples, bandgap generator circuit 502 may correspond to circuit elements 606 and 608 of FIG. 6, and sample and hold circuits 504A, 504B may correspond to circuit elements 626, 628 of FIG. 6. Sample and hold circuits 504A, 504B may also each correspond to circuit 100 of FIG. 1 or circuit 300 of FIG. 3.

As shown in FIG. 11, circuit 500 enables bandgap generator (1102), i.e., to generate reference voltages for a bandgap during a sample operation. Switches S1, S2, S3 are controlled ON and switch S4 is controlled OFF (1104) in the sample operation. Again, S1 corresponds to switch 112 of FIG. 1 or switch 312 of FIG. 3, and S2 corresponds to switch 114 of FIG. 1 or switch 314 of FIG. 3. S3 corresponds to switch 116 of FIG. 1 or switch 316 of FIG. 3, and S3 corresponds to switch 118 of FIG. 1 or switch 318 of FIG. 3.

Next, during a hold operation, circuit 500 disables bandgap generator (1106), e.g., to save power. Switches S1, S2, S3 are controlled OFF and switch S4 is controlled ON (1108) in the hold operation.

FIG. 12 is a flow diagram showing a method of this disclosure. FIG. 12 will be described from the perspective of circuit 100 of FIG. 1 or circuit 300 of FIG. 3. As shown, a method may include a sample phase and a hold phase. In the sample phase, switches S1, S2, S3 are ON and switch S4 is OFF (1202). Again, S1 corresponds to switch 112 of FIG. 1 or switch 312 of FIG. 3, and S2 corresponds to switch 114 of FIG. 1 or switch 314 of FIG. 3. S3 corresponds to switch 116 of FIG. 1 or switch 316 of FIG. 3, and S3 corresponds to switch 118 of FIG. 1 or switch 318 of FIG. 3. In the sample phase, operational amplifier 102, 302 is used for the sample operation of the sample and hold circuit 100, 300 (1204).

In the hold phase, switches S1, S2, S3 are OFF and switch S4 is ON (1206). Moreover, according to the method of FIG. 12, in the hold phase, operational amplifier 102, 302 (or possibly a portion thereof, such as an output stage) is unused for the hold operation of the sample and hold circuit 100, 300. Therefore, the method may include using operational amplifier 102, 302 (or possibly a portion thereof, such as an output stage) by a different circuit during the hold phase (1208), e.g., by a multiplier circuit.

The techniques and circuits of this disclosure may provide solutions to realize sample and hold a very long time with low droop rate. The techniques, in some examples, may be based on two concepts: minimizing the voltages across the devices that control the two leakage currents and exploiting a replica device without including any current mirror. The described solutions allows to achieve robust performance. In one specific example, at 180°C., with a Cₛ=1 pF, the DV after 80 ms is about 0.5 mV, enabling high performance power reduction based on aggressive duty cycle schemes.

In various examples, the described circuits may be embedded in a full bandgap, exploiting the concept of turning on-off the bandgap voltage generator and holding the reference voltages for a long time (i.e., saving power by turning off the bandgap voltage generator).

The techniques described in this disclosure may be implemented in circuitry. In various examples, the techniques may be implemented, at least in part, in circuitry, hardware, software, firmware or any combination thereof. For example, various aspects of the described techniques may be implemented within one or more logical elements, and switch control may be performed by processors, including one or more microcontrollers, microprocessors, digital signal processors (DSPs), application specific integrated circuits (ASICs), field programmable gate arrays (FPGAs), or any other equivalent integrated or discrete logic circuitry, as well as any combinations of such components. The term “processor” or “processing circuitry” may generally refer to any of the foregoing logic circuitry, alone or in combination with other logic circuitry, or any other equivalent circuitry. A control unit comprising hardware may also perform one or more of the techniques of this disclosure.

Such circuitry, hardware, software, and firmware may be implemented within the same device or integrated circuit or within separate devices to support the various operations and functions described in this disclosure. In addition, any of the described units, modules or components may be implemented together or separately as discrete but interoperable logic devices. Depiction of different features as modules or units is intended to highlight different functional aspects and does not necessarily imply that such modules or units must be realized by separate hardware or software components. Rather, functionality associated with one or more modules or units may be performed by separate hardware or software components, or integrated within common or separate hardware or possibly software components.

The techniques of this disclosure may also be described in the following clauses.
Clause 1: A circuit comprising: an operational amplifier including a first op-amp input, a second op-amp input, and an op-amp output; a first switch connected between the first op-amp input and a supply node; a second switch connected between the second op-amp input and the supply node; a first capacitor connected between the first op-amp input and a ground node; a second capacitor connected to the second op-amp input; a third switch connected between the second capacitor and a sample input; and a fourth switch connected between the second capacitor and the op-amp output.
Clause 2: The circuit of clause 1, wherein the circuit is configured to perform a sample and hold operation on the sample input.
Clause 3: The circuit of clause 2, wherein the sample and hold operation holds a sample input voltage on the op-amp output for greater than 100 milliseconds.
Clause 4: The circuit of claim 2 or 3, wherein the sample and hold operation includes a sample phase and a hold phase, wherein a length of the hold phase greater than 500 times a length of the sample phase.
Clause 5: The circuit of clause 4, wherein during the sample phase, the first switch is closed, the second switch is closed, the third switch is closed, and the fourth switch is open, and wherein during the hold phase, the first switch is open, the second switch is open, the third switch is open, and the fourth switch is closed.
Clause 6: The circuit of clause 4 or 5, wherein the sample phase and the hold phase are defined by a clock signal, and the first switch, the second switch, the third switch, and the fourth switch are configured to receive gate control signals that are defined based on the clock signal.
Clause 7: The circuit of any of clauses 1-6, wherein the first switch and second switch are both PMOS transistors that each include a source connection to the supply node and a bulk connection to the supply node.
Clause 8: The circuit of any of clauses 1-7, wherein the first capacitor and the second capacitor are matched with approximately a same capacitance.
Clause 9: The circuit of any of clauses 1-8, wherein the circuit comprises a first sample and hold circuit for a first reference voltage of a bandgap, the circuit further comprising: a second sample and hold circuit for a second reference voltage of the bandgap, wherein the second sample and hold circuit includes the same or similar elements as the first sample and hold circuit.
Clause 10: The circuit of any of clauses 1-8, wherein the circuit is configured to perform a sample and hold operation, and wherein the operational amplifier is further connected to another circuit, wherein the circuit is configured to use the operational amplifier during a sample phase of the sample and hold operation, and the another circuit is configured to use the operational amplifier during a hold phase of the sample and hold operation.
Clause 11: The circuit of clause 10, wherein the circuit comprises a sample and hold circuit and the another circuit comprises a multiplier circuit that operates in a complementary clock phase relative the sample and hold circuit.
Clause 12: The circuit of clause 11, wherein the operational amplifier comprises a two-stage operational amplifier, wherein the sample and hold circuit and the multiplier circuit each comprise a first stage of the two-stage operational amplifier and wherein the sample and hold circuit is configured to use a second stage of the operational amplifier during the sample phase of the sample and hold operation and the multiplier circuit is configured to use the second stage of the operational amplifier during the hold phase of the sample and hold operation.
Clause 13: The circuit of any of clauses 1-12, further comprising a voltage generator circuit, wherein the voltage generator circuit is configured to generate a voltage during a sample phase, and wherein the voltage generator circuit is disabled during a hold phase.
Clause 14: The circuit of clause 13, wherein the voltage generator circuit comprises a bandgap generator that generates a first reference voltage and a second reference voltage, wherein the circuit comprises a first sample and hold circuit for the first reference voltage of a bandgap, the circuit further comprising: a second sample and hold circuit for the second reference voltage of the bandgap, wherein the second sample and hold circuit includes the same or similar elements as the first sample and hold circuit.
Clause 15: The circuit of clause 13 or 14, wherein the voltage generator circuit is configured to generate a voltage reference that is temperature-dependent.
Clause 16: A method of operating a circuit to perform a sample and hold operation on a sample input, wherein the circuit comprises: an operational amplifier including a first op-amp input, a second op-amp input, and an op-amp output; a first switch connected to the first op-amp input and a supply node; a second switch connected to the second op-amp input and the supply node; a first capacitor connected between the first op-amp input and a ground node; a second capacitor connected to the second op-amp input; a third switch connected between the second capacitor and the sample input; and a fourth switch connected between the second capacitor and the op-amp output, the method comprising: performing a sample phase; and performing a hold phase.
Clause 17: The method of clause 16, wherein the sample phase comprises controlling the first switch closed, controlling the second switch closed, controlling the third switch closed, and controlling the fourth switch open, and wherein the hold phase comprises controlling the first switch open, controlling the second switch is open, controlling the third switch open, and controlling the fourth switch closed.
Clause 18: The method of clause 17, wherein the sample phase and the hold phase are defined by a clock signal, wherein the hold phase holds a sample input voltage on the op-amp output for greater than 100 milliseconds and wherein a length of the hold phase greater than 500 times a length of the sample phase.
Clause 19: The method of any of clauses 16-18, wherein the first switch and second switch are both PMOS transistors that each include a source connection to the supply node and a bulk connection to the supply node, and wherein the first capacitor and the second capacitor are matched with approximately a same capacitance.
Clause 20: The method of any of clauses 16-19, wherein the circuit comprises a first sample and hold circuit for a first reference of a bandgap, the circuit further comprising: a second sample and hold circuit for a second reference of the bandgap, wherein the second sample and hold circuit includes the same or similar elements as the first sample and hold circuit, the method further comprising: performing two different sample and hold operations on two different sample inputs of the bandgap.

Various examples of the disclosure have been described. These and other examples are within the scope of the following claims.

What is claimed is:

1. A circuit comprising:
an operational amplifier including a first op-amp input, a second op-amp input, and an op-amp output;
a first switch connected between the first op-amp input and a supply node;
a second switch connected between the second op-amp input and the supply node;
a first capacitor connected between the first op-amp input and a ground node;
a second capacitor connected to the second op-amp input;
a third switch connected between the second capacitor and a sample input; and
a fourth switch connected between the second capacitor and the op-amp output.

2. The circuit of claim 1, wherein the circuit is configured to perform a sample and hold operation on the sample input.

3. The circuit of claim 2, wherein the sample and hold operation holds a sample input voltage on the op-amp output for greater than 100 milliseconds.

4. The circuit of claim 2, wherein the sample and hold operation includes a sample phase and a hold phase, wherein a length of the hold phase greater than 500 times a length of the sample phase.

5. The circuit of claim 4,
wherein during the sample phase, the first switch is closed, the second switch is closed, the third switch is closed, and the fourth switch is open, and
wherein during the hold phase, the first switch is open, the second switch is open, the third switch is open, and the fourth switch is closed.

6. The circuit of claim 5, wherein the sample phase and the hold phase are defined by a clock signal, and the first switch, the second switch, the third switch, and the fourth switch are configured to receive gate control signals that are defined based on the clock signal.

7. The circuit of claim 5, wherein the first switch and second switch are both PMOS transistors that each include a source connection to the supply node and a bulk connection to the supply node.

8. The circuit of claim 1, wherein the first capacitor and the second capacitor are matched with approximately a same capacitance.

9. The circuit of claim 1, wherein the circuit comprises a first sample and hold circuit for a first reference voltage of a bandgap, the circuit further comprising:
a second sample and hold circuit for a second reference voltage of the bandgap, wherein the second sample and hold circuit includes the same or similar elements as the first sample and hold circuit.

10. The circuit of claim 1, wherein the circuit is configured to perform a sample and hold operation, and
wherein the operational amplifier is further connected to another circuit, wherein the circuit is configured to use the operational amplifier during a sample phase of the sample and hold operation, and the another circuit is configured to use the operational amplifier during a hold phase of the sample and hold operation.

11. The circuit of claim 10, wherein the circuit comprises a sample and hold circuit and the another circuit comprises a multiplier circuit that operates in a complementary clock phase relative the sample and hold circuit.

12. The circuit of claim 11, wherein the operational amplifier comprises a two-stage operational amplifier, wherein the sample and hold circuit and the multiplier circuit each comprise a first stage of the two-stage operational amplifier and wherein the sample and hold circuit is configured to use a second stage of the operational amplifier during the sample phase of the sample and hold operation and the multiplier circuit is configured to use the second stage of the operational amplifier during the hold phase of the sample and hold operation.

13. The circuit of claim 1, further comprising a voltage generator circuit, wherein the voltage generator circuit is configured to generate a voltage during a sample phase, and wherein the voltage generator circuit is disabled during a hold phase.

14. The circuit of claim 13,
wherein the voltage generator circuit comprises a bandgap generator that generates a first reference voltage and a second reference voltage,
wherein the circuit comprises a first sample and hold circuit for the first reference voltage of a bandgap, the circuit further comprising:
a second sample and hold circuit for the second reference voltage of the bandgap, wherein the second sample and hold circuit includes the same or similar elements as the first sample and hold circuit.

15. The circuit of claim 13, wherein the voltage generator circuit is configured to generate a voltage reference that is temperature-dependent.

16. A method of operating a circuit to perform a sample and hold operation on a sample input, wherein the circuit comprises:
an operational amplifier including a first op-amp input, a second op-amp input, and an op-amp output;
a first switch connected to the first op-amp input and a supply node;
a second switch connected to the second op-amp input and the supply node;
a first capacitor connected between the first op-amp input and a ground node;
a second capacitor connected to the second op-amp input;
a third switch connected between the second capacitor and the sample input; and
a fourth switch connected between the second capacitor and the op-amp output, the method comprising:
performing a sample phase; and
performing a hold phase.

17. The method of claim 16,
wherein the sample phase comprises controlling the first switch closed, controlling the second switch closed, controlling the third switch closed, and controlling the fourth switch open, and
wherein the hold phase comprises controlling the first switch open, controlling the second switch is open, controlling the third switch open, and controlling the fourth switch closed.

18. The method of claim 17, wherein the sample phase and the hold phase are defined by a clock signal, wherein the hold phase holds a sample input voltage on the op-amp output for greater than 100 milliseconds and wherein a length of the hold phase greater than 500 times a length of the sample phase.

19. The method of claim 16,
wherein the first switch and second switch are both PMOS transistors that each include a source connection to the supply node and a bulk connection to the supply node, and
wherein the first capacitor and the second capacitor are matched with approximately a same capacitance.

20. The method of claim 16,
wherein the circuit comprises a first sample and hold circuit for a first reference of a bandgap, the circuit further comprising:
a second sample and hold circuit for a second reference of the bandgap, wherein the second sample and hold circuit includes the same or similar elements as the first sample and hold circuit, the method further comprising:
performing two different sample and hold operations on two different sample inputs of the bandgap.
